(19) United States
(12) Patent Application Publication
(10) Pub. No.: US 2024/0387084 A1
(43) Pub. Date: Nov. 21, 2024

(54) Magnetic Core for Current Sensors

(71) Applicant: Vacuumschmelze GmbH & Co. KG, Hanau (DE)

(72) Inventor: Daniel Jordan, Hanau (DE)

(21) Appl. No.: 18/564,925

(22) PCT Filed: May 31, 2022
(86) PCT No.: PCT/EP2022/064739

§ 371 Date: Nov. 28, 2023

(30) Foreign Application Priority Data
May 31, 2021 (DE) 10 2021 114 000.5

(51) Int. Cl. H01F 3/10; G01R 19/00; H01F 1/147

(52) U.S. Cl. CPC H01F 3/10; G01R 19/0092; H01F 1/14708; H01F 1/14766

(57) ABSTRACT

The patent application relates to a magnetic core for current sensors. According to one embodiment, the magnetic core comprises a first annular core portion made of a first soft magnetic material and a second annular core portion made of a second soft magnetic material having a lower permeability, a higher saturation induction and a higher coercivity than the first material.

### TECHNICAL AREA

The present description relates to the field of current sensors, in particular a magnetic core for closed-loop compensation current sensors or open-loop current sensors.

### BACKGROUND

For the contactless and therefore potential-free measurement of an electrical current in a conductor, firstly so-called direct imaging current sensors are known, which detect the magnetic flux caused by the current, for example by means of Hall sensors or magnetic field probes, in a magnetic circuit and generate a measurement signal proportional to the current strength. Such direct imaging current sensors are also referred to as open-loop current sensors, which do not have a closed control loop.

Furthermore, compensation current sensors are known in which, with the aid of a closed control loop, a magnetic counter field of the same dimension as the magnetic field of the current to be measured is continuously generated in a magnetic circuit (iron core), so that (almost) complete magnetic field compensation is constantly effectuated and the dimension of the current to be measured can be determined from the parameters for generating the counter field. For higher-frequency currents, a compensation current sensor essentially works as a current transformer due to its iron core.

The properties of the current sensor depend, among other things, on the magnetic properties of the iron core. For a given cross section of the iron core, small measurement errors and a large measurement range are contradictory design goals. For this reason, different alloys for the iron core come into consideration for different applications, wherein the alloy can be optimized for a specific class of applications with regard to its magnetic properties.

The inventors identified a need for a magnetic core for current sensors, which can be used flexibly for various applications and can be produced in a simple manner.

### SUMMARY

A magnetic core for current sensors is described below. According to one exemplary embodiment, the magnetic core has a first annular core part made of a first soft magnetic material and a second annular core part made of a second soft magnetic material, which has a lower permeability, a higher saturation induction, and a higher coercive field strength than the first material.

According to a further exemplary embodiment, the magnetic core has a first annular core part made of a first soft magnetic material and a second annular core part made of a second soft magnetic material, wherein: (1) the first material is a nickel-iron alloy with 69-82 percent by weight nickel and the second material is a nickel-iron alloy with 36-55 percent by weight nickel or (2) the first material is a nickel-iron alloy with 36-55 percent by weight and the second material is a silicon-iron alloy with up to 4 percent by weight silicon or (3) the first material is a nickel-iron alloy with 69-82 percent by weight and the second material is a silicon-iron alloy with up to 4 percent by weight silicon.

### BRIEF DESCRIPTION OF THE DRAWINGS

Exemplary embodiments are explained in more detail below on the basis of illustrations. The illustrations are not necessarily to scale, and the exemplary embodiments are not limited to the illustrated aspects. Rather, representing the principles underlying the exemplary embodiments is valued. In the figures:

FIG. 1 illustrates an example of a compensation current sensor having a flux gate probe one the basis of a block diagram;

FIG. 2 shows a schematic view of a magnetic core for current sensors according to an exemplary embodiment.

FIG. 3 shows a schematic view of a magnetic core according to a further exemplary embodiment.

FIG. 4 illustrates a further exemplary embodiment having wound core parts.

### DETAILED DESCRIPTION

The exemplary embodiments described here relate to a magnetic core for compensation current sensors. Before various aspects of the magnetic core are discussed in detail, the basic structure of a compensation current sensor, which is known per se, will be briefly described in advance. An example is shown in FIG. 1.

According to FIG. 1, the current sensor comprises a soft magnetic core 3, which is magnetically coupled to a primary winding 5 (often only a single turn) and a secondary winding/compensation winding 4. The primary winding 5 carries the primary current i_{P} to be measured and the compensation winding 4 carries the compensation current i_{S} (secondary current). The magnetic flux components caused by the primary current i_{P} and secondary current i_{S} are destructively superimposed in the core 3, wherein the resulting magnetic flux in the core 3 is regulated to zero. The regulation is carried out with the help of the current regulator for the secondary current, which will be described later.

The remaining magnetic flux is measured by means of a magnetic field probe 20, which comprises a ferromagnetic metal strip 21 called a “sensor strip” and a sensor coil 22 enclosing the sensor strip 21. The sensor coil 22 is connected to an evaluation circuit 41, which provides a measured value B representing the magnetic flux. Various suitable evaluation circuits are known per se and will therefore not be explained further here. The evaluation circuit 41 usually comprises an oscillator which generates an excitation current i_{M} which is fed into the sensor coil 22 and magnetizes it periodically with alternating polarity until the sensor strip 21 is saturated. Due to the symmetrical, ideally rectangular hysteresis characteristic of the sensor strip 21, any asymmetry that may be present when the sensor coil 22 is alternately magnetized indicates a magnetic flux in the core 3 that is not equal to zero. This asymmetry can be evaluated. The evaluation circuit is coupled to the current regulator 42, which adjusts the secondary current i_{S} so that the above-mentioned asymmetry disappears or the measured value B (ideally) becomes zero. Such a magnetic field probe is also referred to as a flux gate probe. An example is described, among other things, in DE 102008029475 A1.

In this state (measured value B is zero), the compensation current i_{S} is proportional to the primary current i_{P}, wherein the proportionality factor depends on the ratio of the number of turns of primary winding 5 and compensation winding 4. The regulated compensation current i_{S} can be measured very precisely, for example by means of a measuring resistor R_{S}, and the resulting measured value (for example, the output voltage V_{O}=R_{S}×i_{S}) represents the primary current i_{P} due to the mentioned proportionality.

A current sensor having a flux gate probe requires the magnetic core 3 to guide the magnetic flux of the primary current i_{P} to be measured. Several properties are desirable for the magnetic core. For example, it is to consist of a high-permeability soft magnetic material to “collect” as many field lines as possible. Magnetic hysteresis is a parameter that influences measurement accuracy. The hysteresis is to be as small as possible. The highly-permeable soft magnetic material of the core ideally also offers a high dynamic range without saturation. The core is also to have a defect in order to generate a stray field at a defined position, which can be detected by the probe 20 in order to readjust the compensation current i_{S} (secondary current). If the compensation current sensor is used to measure direct currents (DC currents), the probe 20 detects the stray field of the magnetic core 3 and adjusts the compensation current i_{S} through the compensation winding 4 (see FIG. 1) until the core becomes field-free. However, the defect mentioned must not be so large that the core would be sheared too much, otherwise the inductance will decrease and the converter/transformer behavior will deteriorate. With higher-frequency primary currents, the sensor essentially works as a current transformer due to its iron core and the flux gate probe only plays a subordinate role. A closed, nonsheared magnetic circuit offers the best transformer properties in this operating mode.

Another class of current sensors are so-called open-loop current sensors, in which no compensation winding 4 and therefore also no current regulator 42 is required. In this case, the field which the current i_{P} flowing through the winding 5 generates in an air gap of the magnetic core is measured directly with the aid of the probe 20 (and not indirectly via the compensation current). The magnetic cores described here are suitable for both types of current sensors.

In known sensors, cores made of a material, which can be optimized for the intended area of application of the current sensor with regard to the magnetic material properties, are installed. As mentioned, for a given iron cross section, a small measurement error and a high measurement range are at least partially mutually exclusive design goals. The coercive field strength of the core material directly affects the measurement error. However, known alloys having a low coercive field strength do not have particularly high saturation polarizations, which in turn restricts the usable measuring range. In order to expand this, the iron cross section of the magnetic core would have to be increased, but this is not an option in many applications. However, if alloys optimized with regard to saturation polarization are used, the coercive field strength can also increase (by a factor of up to 3-4). Although the iron core does not saturate as quickly at high field strengths and the primary current to be measured can be increased, the measurement error is larger.

There is therefore a need for improved magnetic cores which combine at least some of the desirable properties explained above as well as possible.

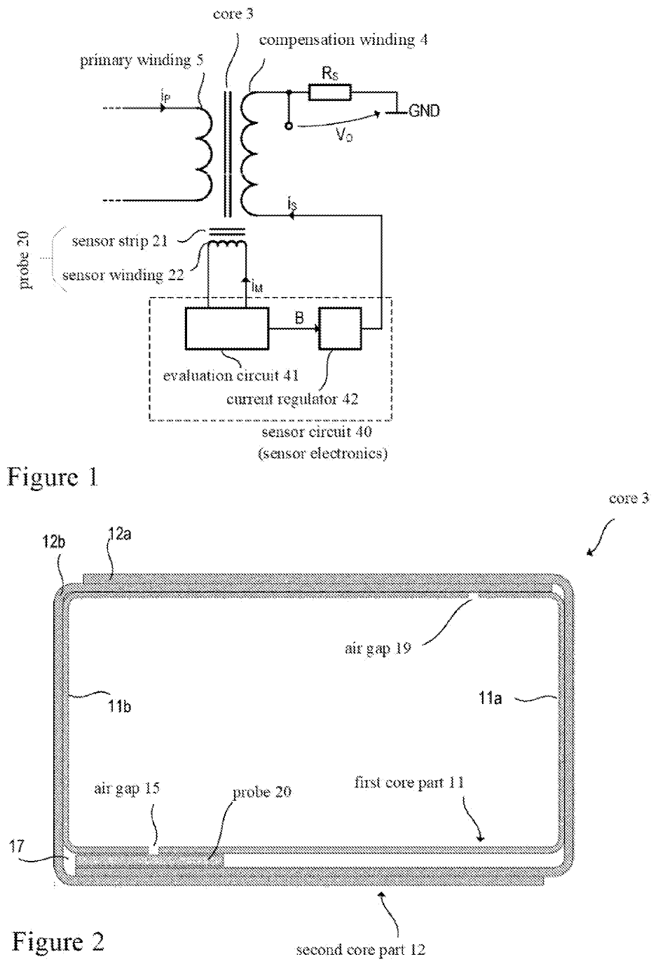

FIG. 2 shows a schematic view of a magnetic core 3 for compensation current sensors according to an exemplary embodiment. According to FIG. 2, the magnetic core 3 has a first (inner) core part 11 and a second (outer) core part 12. In the exemplary embodiments described here, the first core part 11 consists of a first material which has a high permeability, a low saturation induction, and a very low coercive field strength. The second core part 12, on the other hand, consists of a second material which—in comparison to the first material—has a lower permeability, a higher saturation induction, and a higher coercive field strength than the first material. The inner core part has at least one air gap 15, in the immediate vicinity of which the magnetic field probe 20 is arranged.

The first material of the inner core part 11 can be, for example, a nickel-iron alloy having a nickel content of approximately 69-82%, in particular approximately 80%. Commercially available alloys of this type are, for example, Mu-metal and VACOPERM® 100. These materials offer ultralow coercive field strengths, but also only low saturation inductions. The second material of the outer core part 12 can be, for example, a nickel-iron (NiFe) alloy having a nickel content of approximately 36-55%, in particular approximately 50%. A commercially available alloy of this type is, for example, PERMENORM® 5000 V5. This material offers a high saturation induction, but also a higher coercive field strength. The percentages are in percent by weight.

Due to the (relatively) higher permeability of the inner core part 11 and the lower magnetic resistance resulting therefrom, the flux therein predominates and the magnetic field probe 20 can measure the stray flux at the air gap 15 (see FIG. 2).

As mentioned, the outer core part 12 has a higher saturation induction and therefore does not saturate as quickly as the inner core part 11. This can be the case if the primary conductor layer is not optimally selected and the magnetic core 3 is modulated (magnetized) unevenly. For higher primary currents, a combination of 50% NiFe alloy and a SiFe alloy (such as TRAFOPERM® N4) can also be used.

The core parts 11 and 12 are annular. In this context, annular does not mean that the core parts are circular, but rather extend along a closed curve, which does not, however, exclude the presence of an air gap. An annular core can, for example, have a circular, oval, rectangular, square, or hexagonal structure.

The core parts 11 and 12 are produced from a metal strip, which is available in different widths (the strips can be cut to the required width). The strip can be wound into a coil in a manner known per se, cut, and bent, for example, into approximately U-shaped elements 11a, 11b, 12a, 12b. According to the example shown in FIG. 2, the two U-shaped elements 11a and 11b are assembled so that an approximately rectangular structure having air gaps 15 and 19 is formed. This structure forms the inner core part 11. In a similar manner, the U-shaped elements 12a and 12b are assembled. These also form an approximately rectangular structure, but without an air gap. This structure forms the outer core part 12. The U-shaped elements 11a and 11b can have two approximately parallel but unequally long legs. The air gaps 15 and 19 remain between the legs of the elements 11a and 11b. However, the legs of the elements 11a and 11b can also be of equal length. In the example shown, the elements 11a and 11b have the same shape, but are arranged point-symmetrically to one another.

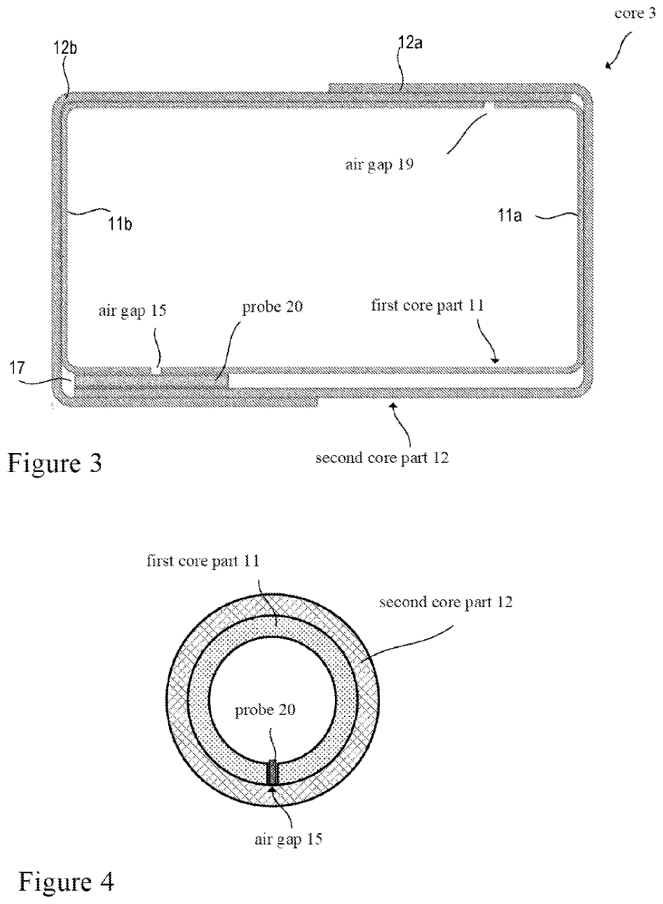

The (for example equally long) legs of the U-shaped elements 12a and 12b abut one another (i.e., are arranged overlapping). The approximately rectangular outer core part 12 formed in this way encloses the inner core part 11. In the example shown in FIG. 2, the inner core part rests in sections (on three of four sides in FIG. 2) directly on the inside of the outer core part 12. In a short section, the inner core part 11 does not directly abut the inside of the outer core part 12 because the magnetic field probe 20 is arranged between them. In the example shown, the magnetic field probe 20 delimits the air gap 15 laterally. The other air gap 19, which lies opposite to the air gap 15, is magnetically short-circuited by the outer core part 11, since at this point the two core parts 11 and 12 directly abut one another. In the example shown in FIG. 3, the only magnetically active air gap is the air gap 15. A magnetic stray field is generated at this during operation, which can be detected by the magnetic field probe 20. The magnetic field probe 20 can be arranged in a corner 17 of the magnetic core 3 between the inner core part 11 and the outer core part 12. The arrangement of the probe 20 on the edge serves for easier production (assembly and winding) thereof.

As mentioned, the first core part 11 and the second core part 12 consist of different materials. The material of the first core part 11 has a high relative permeability ρ_{R}, a low saturation induction B_{S}, and a very low coercive field strength H_{C}. The material of the second core part 12 has—in comparison to the first material—a lower permeability ρ_{R}, a higher saturation induction B_{S}, and a higher coercive field strength He than the first material. In FIG. 2, the first core part 11 (having higher permeability ρ_{R} and lower saturation induction B_{S}) is on the inside and the second core part 12 (having lower permeability ρ_{R} but higher saturation induction B_{S}) is on the outside. It is apparent that this arrangement can also be exchanged so that the core part having higher permeability ρ_{R} (and lower saturation induction B_{S}) is on the outside.

The individual core elements 11a, 11b, 12a, 12b consist of a large number of strip layers (similar to a cut strip core). By varying the thickness and width of the tape, the size of the resulting magnetic core is very easily scalable. The first core part 11, which has the air gap 15, can consist of only a few layers of an amorphous or nanocrystalline alloy.

FIG. 3 shows a further exemplary embodiment, which essentially represents a modification of the example from FIG. 2. Unlike FIG. 2, in the present example the legs of the core elements 12a and 12b, of which the outer core part 12 is composed, are not of the same length. Nevertheless, as in the previous example, the legs of the U-shaped element 12a directly abut the corresponding legs of the element 12b, by which the rectangular structure is formed which represents the outer core part 12. Otherwise, the example shown in FIG. 3 is the same as FIG. 2 and reference is made to the above statements.

FIG. 4 illustrates a further exemplary embodiment of a magnetic core for current sensors. The magnetic core again consists of two annular core parts 11 and 12 made of soft magnetic material. In the example shown, the core parts 11 and 12 are circular, wherein the inner core part 11 can be slotted. It therefore has an air gap 15. The outer core part 12 has no air gap. The inner core part 11 is made of a first soft magnetic material and the outer core part 12 is made of a second soft magnetic material, which has a lower permeability ρ_{R}, a higher saturation induction B_{S}, and a higher coercive field strength He than the first material.

The two core parts 11 and 12 can be produced, for example, by winding a soft magnetic tape. In this case, the two core parts 11 and 12 are toroidal cores per se, i.e., the magnetic core according to FIG. 4 consists of two coaxially arranged toroidal core parts 11, 12, wherein only the inner core part 11 has an air gap. The magnetic field probe 20 is arranged in the air gap 15 or on the air gap 15. In the case of compensation current sensors, the magnetic field probe 20 is, for example, a flux gate probe; in the case of open-loop current sensors, Hall sensors or magnetoresistive (MR) sensors are also often used as magnetic field probes.

The material combination used can, for example, be a combination of a NiFe alloy having a nickel content of 69-82 percent by weight (first material) and a NiFe alloy having a nickel content of 36-55 percent by weight (second material). For example, VACOPERM® 100 (first material, approximately 77% nickel) has a relative permeability ρ_{R} of 350,000; the saturation polarization B_{S} is 0.74 Tesla (T) and the coercive field strength He is 0.8 amperes per meter (A/m). PERMENORM® 5000 V5 (second material, 45-50% nickel) has a permeability ρ_{R} of 135,000, a saturation polarization B_{S} of 1.55 T, and a coercive field strength He of 4 A/m.

For higher primary currents, a material such as PERMENORM® 5000 V5 (second material) can be used for the inner core part 11 and a SiFe alloy having at most 4% silicon such as TRAFOPERM® N4 (third material, approximately 3% silicon) can be used for the outer core part 12 as a third material. TRAFOPERM® has a relative permeability ρ_{R} of 30,000, a saturation polarization B_{S} of 2.03 T, and a coercive field strength He of 20 A/m. It is apparent that the numerical values mentioned are only to be understood as examples. It can be seen that in NiFe alloys the permeability increases and the saturation polarization decreases as the nickel content increases. For SiFe alloys, the permeability is lower than for NiFe alloys and the saturation polarization is greater.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although various embodiments have been illustrated and described with respect to one or more specific implementations, alterations and/or modifications may be made to the illustrated examples without departing from the spirit and scope of the appended claims. With particular regard to the various functions performed by the above described components or structures (units, assemblies, devices, circuits, systems, etc.), the terms (including a reference to a “means”) used to describe such components are intended to correspond—unless otherwise indicated—to any component or structure that performs the specified function of the described component (e.g., that is functionally equivalent), even if it is not structurally equivalent to the disclosed structure that performs the function in the herein illustrated exemplary implementations of the invention.

It will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-21. (canceled)

22. A magnetic core for current sensors, the magnetic core comprising:
a first annular core part made of a first soft magnetic material; and
a second annular core part made of a second soft magnetic material which has a lower permeability, a higher saturation induction, and a higher coercive field strength than the first soft magnetic material.

23. The magnetic core of claim 22, wherein the second annular core part encloses the first annular core part on the outside, or the first annular core part encloses the second annular core part on the outside.

24. The magnetic core of claim 22, wherein the first annular core part comprises two elements joined together, and wherein there is at least one air gap between the two elements.

25. The magnetic core of claim 24, wherein the two elements of the first annular core part are essentially U-shaped.

26. The magnetic core of claim 25, wherein the two U-shaped elements are identical and each have two legs of different lengths.

27. The magnetic core of claim 22, wherein the second annular core part comprises two elements which are joined together without an air gap and abut one another in a partially overlapping manner.

28. The magnetic core of claim 27, wherein the two elements of the second annular core part are essentially U-shaped and have legs of the same or different lengths.

29. The magnetic core of claim 22, wherein the first annular core part and the second annular core part abut one another at least in sections.

30. The magnetic core of claim 29, wherein the first annular core part and the second annular core part have a substantially rectangular shape and abut one another on three of four sides of the rectangular shape.

31. The magnetic core of claim 22, wherein the first annular core part and the second annular core part have a substantially rectangular shape and abut one another on three of four sides of the rectangular shape.

32. The magnetic core of claim 22, wherein the first annular core part and the second annular core part are spaced apart from one another along a section in which a magnetic field probe is arranged between the first annular core part and the second annular core part.

33. The magnetic core of claim 32, wherein the first annular core part comprises two elements joined together, wherein there is at least one air gap between the two elements, and wherein the magnetic field probe laterally delimits the at least one air gap.

34. The magnetic core of claim 22, wherein the first annular core part is a toroidal core with an air gap and the second annular core part is a toroidal core without an air gap, and wherein the second annular core part encloses the first annular core part or the first annular core part encloses the second annular core part.

35. The magnetic core of claim 34, wherein the first annular core part and the second annular core part are each toroidal strip cores or comprise stamped sheet metal stacks.

36. The magnetic core of claim 22, wherein the first soft magnetic material is a nickel-iron alloy which comprises approximately 69 to 82 percent by weight nickel.

37. The magnetic core of claim 22, wherein the second soft magnetic material is a nickel-iron alloy which comprises approximately 36 to 55 percent by weight nickel or, wherein the second soft magnetic material is a silicon-iron alloy which comprises up to 4 percent by weight silicon.

38. The magnetic core of claim 22, wherein the first soft magnetic material is a nickel-iron alloy which comprises approximately 36 to 55 percent by weight nickel and, wherein the second soft magnetic material is a silicon-iron alloy which comprises up to 4 percent by weight silicon.

39. A compensation current sensor, comprising:
the magnetic core of claim 22;
a primary winding arranged around the magnetic core;
a secondary winding arranged around the magnetic core; and
a sensor circuit designed to feed a secondary current into the secondary winding based on a measurement signal generated with the aid of a magnetic field probe, and which represents a magnetic flux density present in the magnetic core.

40. An open-loop current sensor, comprising:
the magnetic core of claim 22;
a primary winding arranged around the magnetic core; and
a sensor circuit designed to generate a measurement signal which represents a magnetic flux density present in the magnetic core, with the aid of a magnetic field probe.

41. A magnetic core for current sensors, the magnetic core comprising:
a first annular core part made of a first soft magnetic material; and
a second annular core part made of a second soft magnetic material,
wherein the first soft magnetic material is a nickel-iron alloy with 69-82 percent by weight nickel and the second soft magnetic material is a nickel-iron alloy with 36-55 percent by weight nickel, or the first soft magnetic material is a nickel-iron alloy with 36-55 percent by weight and the second soft magnetic material is a silicon-iron alloy with up to 4 percent by weight silicon, or the first soft magnetic material is a nickel-iron alloy with 69-82 percent by weight and the second soft magnetic material is a silicon-iron alloy with up to 4 percent by weight silicon.

42. The magnetic core of claim 41, wherein the second annular core part encloses the first annular core part on the outside, or the first annular core part encloses the second annular core part on the outside.
